(19) United States
(12) Patent Application Publication
(10) Pub. No.: US 2024/0402443 A1
(43) Pub. Date: Dec. 5, 2024

(54) KINEMATICALLY ALIGNED OPTICAL CONNECTOR FOR SILICON PHOTONIC INTEGRATED CIRCUITS (PICs) AND METHOD FOR MAKING SAME

(71) Applicant: Intel Corporation, Santa Clara, CA (US)

(72) Inventors: John M. Heck, Berkeley, CA (US); Saeed Fathololoumi, Los Gatos, CA (US); Harel Frish, Albuquerque, NM (US); Sang Yup Kim, Sunnyvale, CA (US); Hari Mahalingam, San Jose, CA (US); Nicholas D. Psaila, Lanark (GB)

(73) Assignee: Intel Corporation, Santa Clara, CA (US)

(21) Appl. No.: 18/325,512

(22) Filed: May 30, 2023

(51) Int. Cl. G02B 6/42; H01L 25/16

(52) U.S. Cl. CPC G02B 6/423; G02B 6/4266; H01L 25/167

(57) ABSTRACT

A kinematically aligned optical connector may be implemented with a silicon PIC component and a glass substrate component. The kinematically aligned optical connector includes one or more kinematic connectors or mechanical alignment features and visual fiducials that enable true kinematic coupling (i.e., in a three-dimensional Cartesian coordinate system, full constraint in all 6 degrees of freedom, meaning, X, Y, Z planes and all 3 angles), and enables an increased thickness of the glass substrate material of the glass waveguide substrate.

### BACKGROUND

Many multi-die assemblies require a silicon photonic integrated circuit (PIC) to be optically connected to a glass waveguide substrate. In support of this, various passive and active optical alignment approaches have been developed to assure or optimize alignment efficiency. However, continued improvements to optical alignment approaches are desired.

### BRIEF DESCRIPTION OF THE DRAWINGS

FIG. 1A is a simplified view of an exemplary system including a photonic integrated circuit (PIC) die with a kinematically aligned optical connector, in accordance with various embodiments.

FIGS. 1B-1C are simplified views of an embodiment of the kinematic connector in FIG. 1A.

FIGS. 2A-2B are simplified views of an embodiment of the kinematic connector in FIG. 1A.

FIG. 3A is a simplified view of another PIC die plan for a system including a photonic integrated circuit (PIC) die with a kinematically aligned optical connector, in accordance with various embodiments.

FIGS. 3B-3C are a simplified views of additional embodiments of the kinematic connector as may be implemented in FIG. 1A or FIG. 3A.

FIG. 4 is a simplified view of a system with another PIC die plan for a system including a photonic integrated circuit (PIC) die with a kinematically aligned optical connector, in accordance with various embodiments.

FIG. 5 is a simplified view of yet another PIC die plan for a system including a photonic integrated circuit (PIC) die with a kinematically aligned optical connector, in accordance with various embodiments.

FIG. 6 illustrates an exemplary multi-die assembly based on provided embodiments.

FIG. 7 is an exemplary method for making a system including a photonic integrated circuit (PIC) die with a kinematically aligned optical connector, in accordance with various embodiments.

FIG. 8 is a simplified cross-sectional side view of a multi-chip package that includes a photonic integrated circuit (PIC) with an apparatus for optical alignment, in accordance with various embodiments.

FIG. 9 is a top view of a wafer and dies that may be included in a microelectronic assembly, in accordance with any of the embodiments disclosed herein.

FIG. 10 is a simplified cross-sectional side view showing an implementation of an integrated circuit on a die that may be included in various embodiments, in accordance with any of the embodiments disclosed herein.

FIG. 11 is a cross-sectional side view of a microelectronic assembly that may include any of the embodiments disclosed herein.

FIG. 12 is a block diagram of an example electrical device that may include any of the embodiments disclosed herein.

### DETAILED DESCRIPTION

The following detailed description is merely exemplary in nature and is not intended to limit the application and uses. It may be evident that the novel embodiments can be practiced without every detail described herein. For the sake of brevity, well known structures and devices may be shown in block diagram form to facilitate a description thereof.

In various optical modules and multi-die assemblies, a silicon photonic integrated circuit (PIC) may be required to optically connect to a glass waveguide substrate. Optical connectors including fiber array units (FAUs) may also be utilized. Ensuring a robust interface (i.e., optimized optical alignment) between the PIC and the optical connector is a technical problem to solve.

Some solutions to this technical problem are passive alignment schemes. One example of a passive alignment scheme being developed utilizes a lithography process to create a precision v-groove feature to locate fibers therein; another implements an optical wire (vision based passive placement); still another implements an in-situ laser write optical waveguide etc.

V-grooves designed for fiber alignment can sometimes be overkill for connecting a single-piece glass waveguide substrate to a silicon PIC, as the large contact area is susceptible to particulate contamination which can strongly impact yield. Additionally, in certain applications where the silicon PIC is flip chip bonded to a package substrate, a glass coupler component can introduce a significant protrusion beyond the silicon PIC surface. In these scenarios, the thickness of the glass coupler component can be limited by a glass substrate sized to accommodate the respective glass fiber diameter. This relationship can limit the strength of the glass substrate, making it vulnerable to cracking of the glass substrate and susceptible to misalignment due to substrate warpage (and hence affecting both glass coupler component yield and final product yield). It is challenging for passive alignment schemes to be competitive with active alignment schemes on either coupling efficiency or on cost in the short term (due to relying on equipment for a remarkably high precision pick and placement or in-situ processing).

Other solutions include active alignment schemes. Many active alignment schemes are slow and tedious and require powering up the silicon photonics integrated circuit (PIC). In scenarios using a transmitter, then measuring the light power coupled into outgoing fiber(s) using photodiodes and establishing a feedback loop between coupled power and an optical component (such as a lens) holder position. When more than one optical component is being aligned (such as a number of waveguides aligned with an array of fibers in a fiber block, using a single-piece lens array), the lasers at the source may need to be switched on and off and/or a number of output channels must be analyzed at the same time to obtain the needed information for optimizing alignment. The fiber block referred to herein may hold the optical fibers only, or it may be butt-coupled to a Planar Light Circuitry (PLC) composed of an array of waveguides. Active alignment can realize a reliable optimum optical coupling as compared to passive alignment, but it is time consuming, requires complicated handling and setup to power on the PIC sub-assembly, and is generally expensive. Accordingly, it is desirable to provide improved optical alignment methods and apparatus.

The present disclosure provides a technical solution to the above-described problems related to optical alignment and provides an improvement over the limitations of available solutions, in the form of a kinematically aligned optical connector for silicon photonic integrated circuits (PICs) and method for making same.

The disclosed kinematically aligned optical connector may be implemented with a silicon PIC component and a glass substrate component. Aspects of the disclosure are characterized by (1) one or more kinematic connectors or mechanical alignment features and visual fiducials that enable true kinematic coupling (i.e., full constraint in six degrees of freedom, i.e., x, y, z, and all 3 angles), and (2) a maximized thickness of the glass substrate material of the glass waveguide substrate (over available solutions) to ensure a high mechanical strength during assembly and minimize in-use warpage. Embodiments can significantly improve the accuracy, yield/cost, assembly throughput, reliability, and in-use strength of the optical connector, which is one of the most technically challenging aspects of optical module or multi-die assembly. The optical connector, its implementation in a PIC die and associated glass substrate, and an exemplary method for making same is described in more detail in connection with the figures below.

Exemplary embodiments will hereinafter be described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The term “overlaid” (past participle of “overlay”) may be used to refer to a layer to describe a location and orientation for the layer but does not imply a method for achieving the location and orientation. For example, a first layer overlaid on a second layer, or overlaid on a component means that the first layer is spread across or superimposed on the second layer or component. Accordingly, a layer that is overlaid on a second layer may be viewed in a cross-sectional view as adjacent to the second layer.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB).

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps or leads attached to the package substrate for attaching the packaged integrated circuit component to a printed circuit board or motherboard.

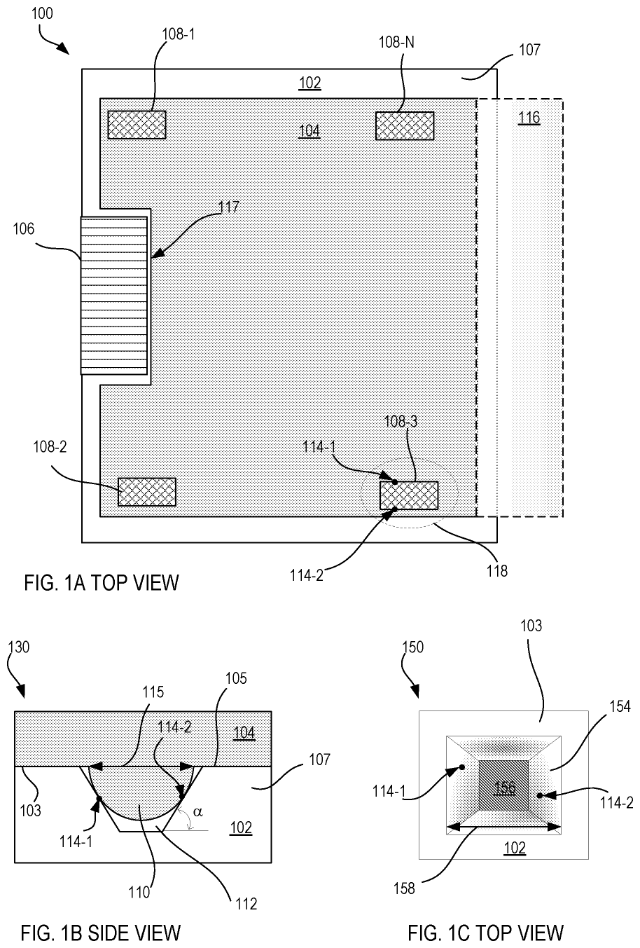

FIG. 1A is a simplified view of an exemplary system 100 including a photonic integrated circuit (PIC) die with a kinematically aligned optical connector, in accordance with various embodiments. FIGS. 1B-1C are simplified views of an embodiment of the kinematic connector 118 in FIG. 1A. Embodiments of the system are characterized by the geometry and spatial relationships described herein.

A semiconductor substrate 107 including a photonic integrated circuit (PIC) is indicated as PIC 102 die. As may be appreciated, the PIC 102 die includes a miniaturized circuit that integrates various electric and photonic components, such as lasers, modulators, detectors, and waveguides. The PIC 102 die includes one or more optical channels or waveguides. Waveguides in the silicon PIC 102 die are referred to herein as “main waveguides” to distinguish them from waveguides found in glass, described below. Many PICs 102 have a plurality of main waveguides 106. Individuals of the main waveguides 106 may be routed differently around the silicon substrate and then collectively terminate at a facet 117, an edge, or on a surface of the PIC 102 die. The facet 117 is where they can be connected to external optical components (in FIG. 1A, this facet is indicated on the left edge of the illustration).

The PIC 102 die may have a silicon substrate layer or core of about 250-750 microns thick (wherein “about” means plus or minus 10%). The main waveguides 106 may comprise silicon nitride. The main waveguides 106 may be encased in a transparent dielectric material or cladding layer comprising oxygen and may include silicon dioxide. In practice, it may be difficult to distinguish the transparent dielectric material from the substrate layer in a cross-sectional scanning electron microscopy image (SEM), however, a non-limiting way to identify the described embodiments is to visually inspect both the materials present in a top down and/or cross-sectional view and the structure and shape of the materials to determine that the described embodiments have been implemented.

Proposed embodiments of the optical connector implement one or more kinematic joints or connectors 108-1, 108-2, 108-3 . . . 108-N to kinematically couple a glass waveguide substrate 104 to the PIC 102 die. As used herein, “glass” can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO₂. Al₂O₃, B₂O₃, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles.

The glass waveguide substrate 104 is understood to include multiple glass waveguides to optically (kinematically) couple to the main waveguides. A kinematic coupling is a type of mechanical joint that provides precise and repeatable alignment between two objects or components. A kinematic coupling relies on the geometry of the joint (e.g., the connectors herein) rather than external forces to hold the components together. In a kinematic coupling, the two components are designed with matching geometry that interlocks precisely when brought together. This interlocking mechanism (embodied as the kinematic connectors) allows the components to be joined with high accuracy and repeatability. The kinematic coupling provided by the kinematic connectors 108x assure an optical connection between individual main waveguides 106 and respective glass waveguides within the glass waveguide substrate 104.

Side view 130 depicts a PIC 102 die that has a top surface 103 that includes or defines a cavity 112 therein. The cavity 112 may alternately be referred to as a pit, a pocket, or a v-groove, depending in part on a methodology for creating the cavity 112 (described in more detail below). The cavity 112 is a surface feature etched into the surface and defined in part by cavity sidewalls. The cavity 112 can embody a variety of shapes. In view 150, the cavity 112 shape appears like an inverted pyramid; four cavity sidewalls 154 having widths 158 (measured at the top surface 103) that are substantially equal slope downward/inward toward each other, at an angle α of substantially 54.7 degrees (measured from a horizontal plane) that terminates at a cavity floor 156. As used herein, “substantially” means plus or minus 20%, and the measure of 54.7 degrees reflects an available etching result. The cavity sidewalls slope toward each other as the eye travels the side view from the top surface 103 toward the center of the silicon substrate. The cavity 112 may have the cavity floor 156, or the sidewalls may extend downward to self-terminate, or meet each other, at a line or point, which could look like a v-groove in the side view 130. If there is a cavity floor 156, it will have a smaller area than an area of the opening of the cavity at the top surface 103.

In this non-limiting embodiment, the glass waveguide substrate 104 includes, for every cavity 112 on the PIC 102 die, a respective feature 110, in a 1:1 ratio. The feature 110 is created on the glass waveguide substrate and comprises glass. The feature 110 extends from a lower surface 105 of the glass substrate, as illustrated. In various embodiments, the feature may extend substantially perpendicularly from the lower surface 105. Those with skill in the art will recognize that “top surface” and “lower surface” are used in the description of the figures to assist in comprehending the concepts, and that the images can be flipped such that the PIC 102 die on the top and the glass waveguide substrate 104 on the bottom, in which case the labels “top” and “lower” may be interchanged.

The feature 110 may be hemispherical, as shown in view 130, defined with a diameter 115 at its base and radius of curvature, or may have other shapes. Regardless of the shape of the feature 110, the feature 110 is to connect with sidewalls 154 in two or more locations or regions that contact, illustrated as 114-1 and 114-2, but the feature 110 does not contact the cavity floor 156. In various embodiments, the feature 110 has a largest dimension (generally, a width or diameter) of substantially 40 microns. In other embodiments, the feature 110 has the largest dimension of substantially 70 microns. In further embodiments, the feature 110 has the largest dimension of substantially 100 microns.

When the glass waveguide substrate 104 is kinematically aligned with the PIC 102, a portion of the glass waveguide substrate 104 overlaps with the semiconductor substrate comprising the PIC 102 die. Said differently, the portion of the glass waveguide substrate 104 is configured to fit with or overlaid upon, the PIC 102 die. In various embodiments, a corresponding region of the semiconductor substrate comprising the PIC 102 die is thinned with respect to another region of the semiconductor substrate with the PIC 102 die to accommodate this portion of the glass waveguide substrate 104, enabling the respective area of the glass waveguide substrate 104 to be thicker. Additionally, the glass waveguide substrate 104 is to route optical signals in the glass waveguides from the PIC 102 die to one or more external optical components; therefore, the glass waveguide substrate 104 may extend beyond a peripheral edge of the PIC 102 die (or die cutting line), as indicated with the dashed lines representing area 116. In various aspects of the disclosure, the glass waveguide substrate 104 has a thickness of substantially 300 microns in the overlap portion, and the thickness is increased greater than 300 microns in area 116, beyond the PIC 102 die.

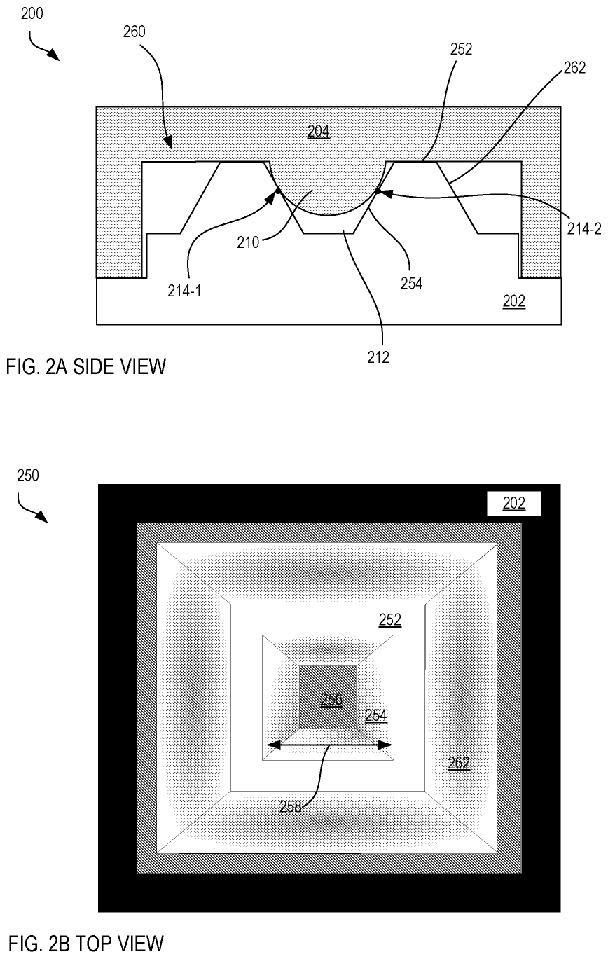

FIGS. 2A-2B are simplified views of an embodiment of the kinematic connector in FIG. 1A. View 200 and view 250 depict the PIC 202 die with a pyramidal pit or cavity 212 created on a raised plateau area, with other features being like those described in views 130 and 150. For example, sidewalls 254 of substantially equal width 258 at top surface 252 slope inward and downward to a cavity floor 256. Once again, there are at least two regions that contact for the feature 210 on the glass waveguide substrate 204, indicated with 214-1 and 214-2. In this embodiment of a kinematic connector, the silicon substrate of the PIC 202 die may be built up before creating the cavity 212, as illustrated. Additional sidewalls 260 that are external to the formed cavity 212, slope downward and outward to a plateau of the built-up silicon substrate, which drops off to a thinned region of the silicon substrate of the PIC 202 die. Embodiments implementing this kinematic connector variation may also thin the glass of the glass waveguide substrate to accommodate the thickened silicon substrate without adding any overall height. The thinned glass region in this embodiment is indicated with arrow 260.

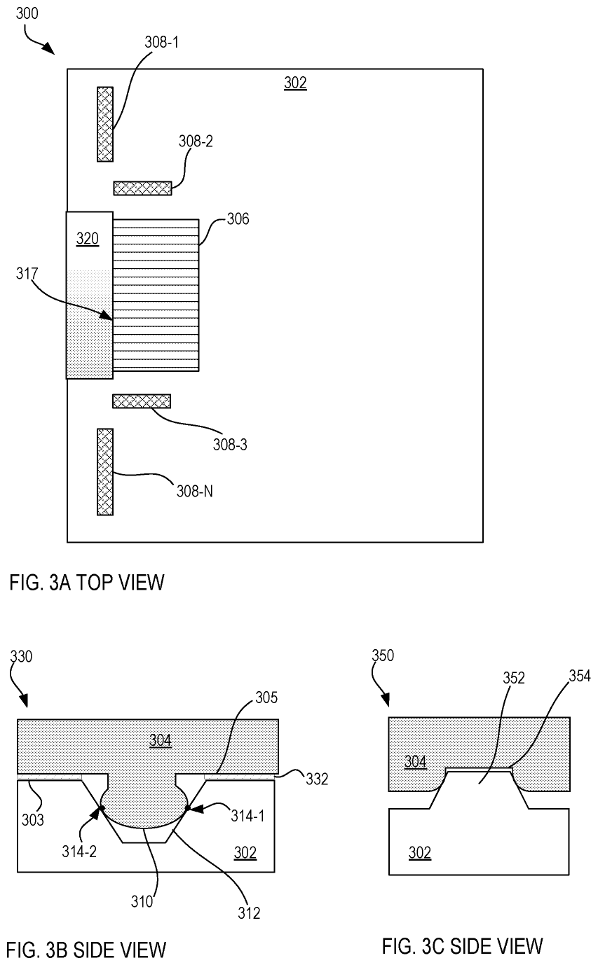

As may be appreciated, the cavities 112/212 need not be square or pyramidal, additionally, the features 110/210 may take other shapes. FIG. 3A illustrates a simplified view of another PIC 302 die plan for a system including a photonic integrated circuit (PIC) die with a kinematically aligned optical connector, in accordance with various embodiments. PIC 302 die has cavities 308-1, 308-2, 308-3 . . . 308-N that are long and trench-like (e.g., having a first two substantially parallel sidewalls on which the respective two regions that contact are located, with an opposing two sidewalls appearing open).

Additionally, the number of cavities and locations for individual cavities can vary across optical connector applications. In view 300, trench cavities are located near the left side of the PIC 302 die boundary. Additionally, some PIC 102 die plans may include a coupling recess or edge cavity 320 alongside the PIC main waveguides 306 facet, as illustrated in view 300.

Cavities 308-1, 308-2, 308-3, . . . 308-N can be created using available v-groove methodologies. V-grooves are typically created by etching a thin layer of silicon or other suitable material, such as silica or quartz, with a “V”-shaped channel. The channel can be coated with a reflective material, such as gold or aluminum, to enhance the coupling efficiency between the optical fibers or waveguides and a photonic integrated circuit (PIC).

View 300 illustrates a silicon v-groove to mate with the features, similar to the way glass fibers can be aligned in v-grooves. A benefit of using v-grooves is that the v-grooves can be placed in a small number of locations (i.e., less than the number of optical channels, and they can even be oriented in both X and Y directions, as shown. In a variation on this embodiment, the PIC die plan would include only the alignment cavities oriented along the horizontal axis (cavities 308-2 and 308-3), omitting those oriented perpendicularly. In this case, the optical connector or glass waveguide substrate could be slid horizontally from the right toward the left of the PIC 302 die, such that the v-groove acts as a hard-stop feature, inhibiting further motion (much the way a fiber would be aligned in a V-groove).

FIGS. 3B-3C are a simplified views of additional embodiments of the kinematic connector as may be implemented in FIG. 1A or FIG. 3A. In view 330, the feature 310 appears as an inverted spherical knob atop a pillar. An adhesive layer 332 is shown between the lower surface 305 of the glass waveguide substrate 304 and the top surface 303 of the PIC 302 die; this adhesive layer 332 may be present in any of the previously described connector embodiments, and it may extend past the surface and over the sidewalls and into the cavity 312. The two or more contact points 314-1 and 314-2 are illustrated. In an alternate embodiment illustrated with view 350, the PIC 302 die can have the feature 352 extending upward, from its top surface upward, and the glass waveguide substrate 304 can have its lower surface 305 define a cavity 354 to receive the feature 352. The protruding pyramidal feature can be created on the silicon substrate of the PIC die using crystallographic (111) planes, and these can be mated with corresponding cavities 354 on the glass waveguide substrate 304 as shown. Note that in this case, a technique known as corner compensation (known by persons with skill in the crystallographic etching art) may need to be applied, otherwise the (111) faces of the protruding silicon pyramids could suffer from positional inaccuracy.

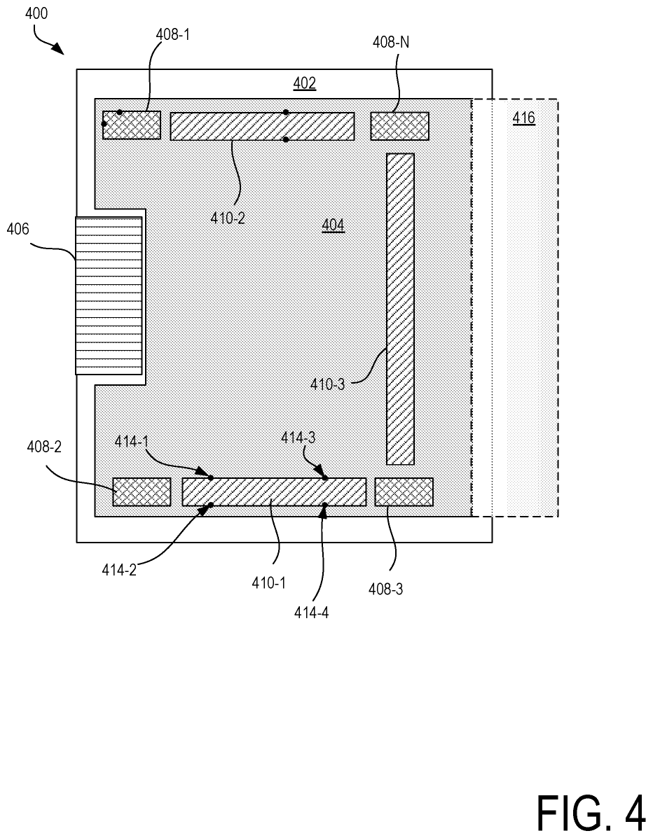

FIG. 4 is a simplified view of a system with another PIC die plan for a system including a photonic integrated circuit (PIC) die with a kinematically aligned optical connector, in accordance with various embodiments. View 400 shows a system implementing the kinematic connectors as a combination of both pyramidal pits/cavities (408-1, 408-2, 408-3, . . . 408-N) and trench cavities (410-1, 410-2, 410-3) in the PIC 402 die. Main waveguides 406 may edge connect (edge-coupling) as shown. Exemplary regions that contact are indicated with pairs of dots distributed in the figure to suggest a variation of other locations for regions that contact. Notably, in FIG. 4, a single v-groove 410-1 can accommodate more than one feature at two locations spaced away from each other, e.g., one feature could connect at regions 414-1 and 414-2 and second feature could connect at 414-3 and 414-4. Features (not shown) on the glass waveguide substrate 404 in the portion that overlaps with the silicon substrate material are as described above to assure kinematic coupling. Optional extension 416 is a region in which a glass thickness may be increased.

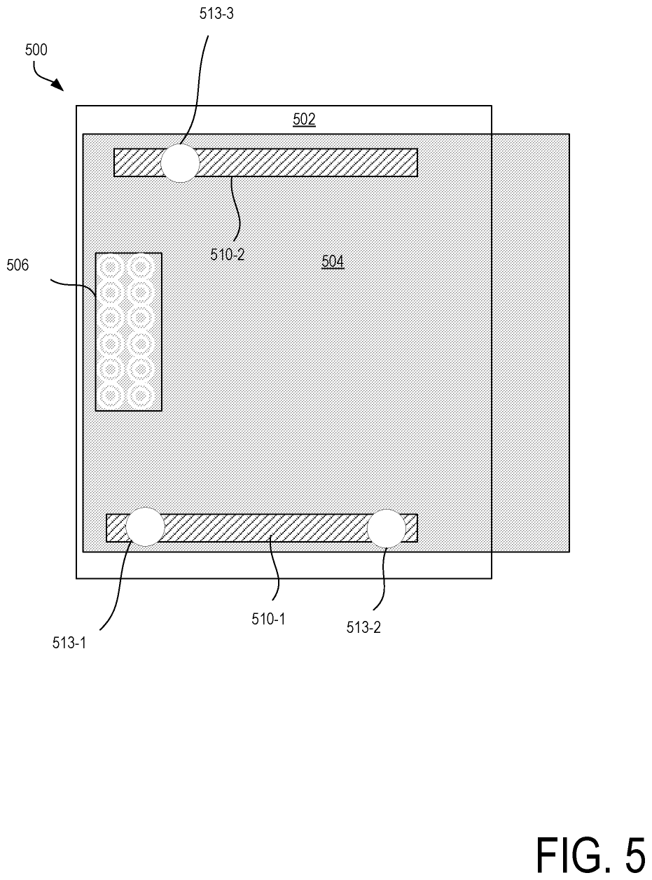

FIG. 5 is a simplified view of yet another PIC die plan for a system including a photonic integrated circuit (PIC) 502 die with a kinematically aligned optical connector, in accordance with various embodiments. View 500 shows the use of just two v-grooves for cavities (510-1 and 510-2) for the kinematic connectors. In this non-limiting embodiment, the glass waveguide substrate 504 implements two features (513-1 and 513-2) in a first cavity (510-1) on the lower edge (2:1 ratio) and one feature 513-3 in a second cavity 510-2 on the upper edge (1:1 ratio). In view 500, the main waveguides 506 are illustrated differently to indicate vertical optical coupling from the main waveguides 506 to the glass waveguide substrate 504 can be achieved, using evanescent coupling, such as based on a compliant polymer. In this application, light can leak upwards along the length of the main waveguides 506.

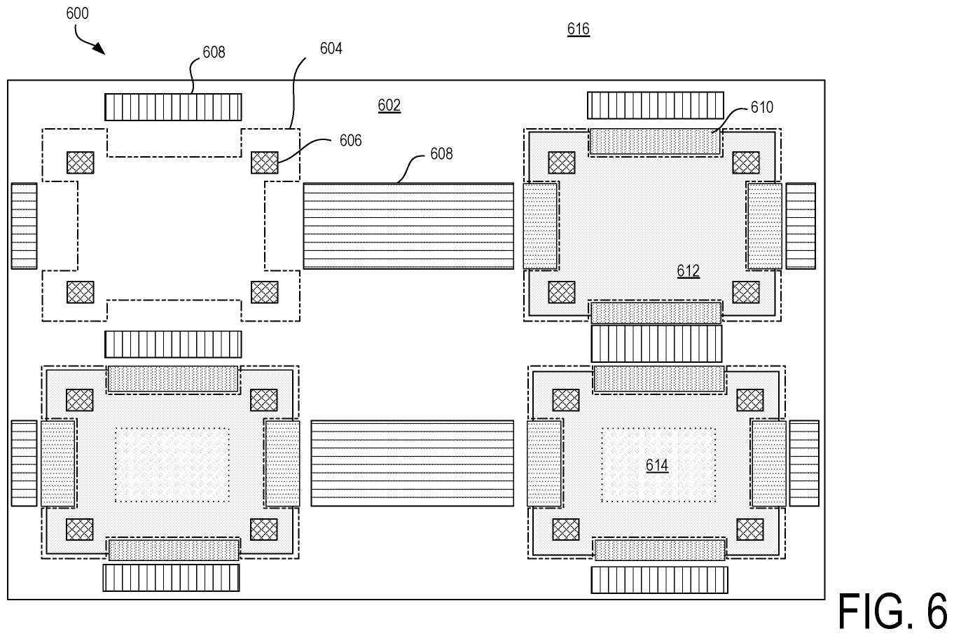

Once kinematically coupled, the PIC die/glass waveguide substrate assembly can be part of a larger die stack assembly including one or more electrical IC's and bonded to a glass interposer. FIG. 6 illustrates an exemplary multi-die semiconductor assembly based on provided embodiments. In the non-limiting example of view 600, shading is used to convey like components so that labeling does not make the figure too busy. Glass interposer 602 supports electrical and optical connection regions (glass substrate waveguides 608), can have through glass vias (TGVs) and can have cavities for integrated circuits (ICs). Outline 604 is a possible outline for a cavity in the glass interposer 602 for placing a PIC 612 therein. Kinematic alignment features 606 can take any of the embodiments described above. Optical coupling interfaces 610 are distributed around the PICS 612, representing optical connection locations for PIC main waveguides with glass substrate waveguides 608. The PICs may also have regions 614 reserved for electrical connections, such as solder balls solder bumps, or the like. In addition to the optical waveguides (glass substrate waveguides 608) there can be metal routing layers around/on/through the glass interposer 602. In a further package assembly, the embodiment of view 600 could have a heat spreader attached and could also be placed on a motherboard or other package substrate.

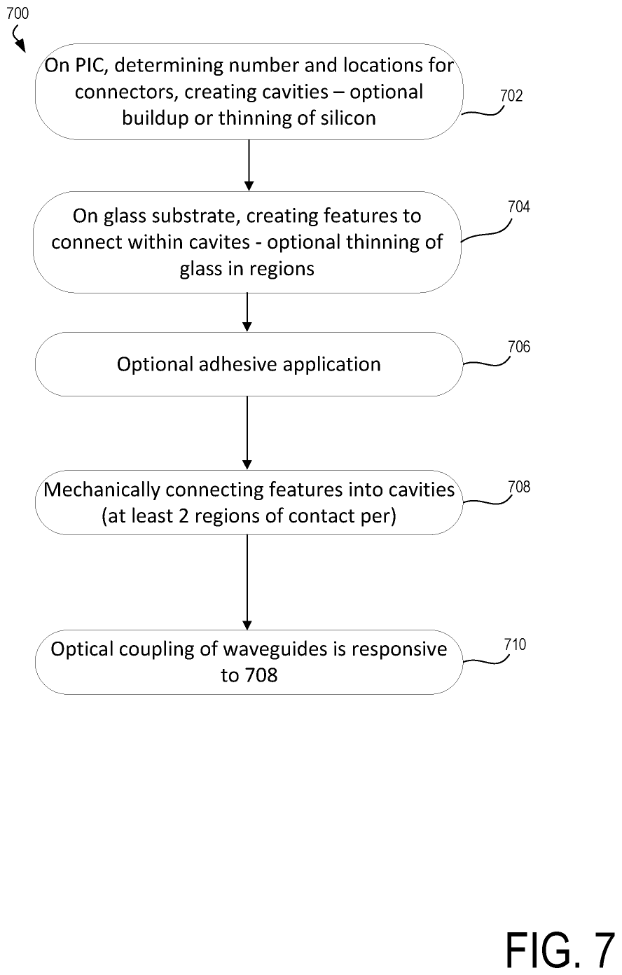

FIG. 7 is an exemplary method 700 for making a system including a photonic integrated circuit (PIC) die with a kinematically aligned optical connector, in accordance with various embodiments. At 702, the PIC 102 die may have been fully manufactured before creating the cavities 112. An application-specific analysis of the intended kinematically aligned optical connector application informs the determination of intended number and location for individual kinematic connectors. The cavities 112 can be created in a crystalline silicon substrate (having the PIC and waveguides therein) at the predetermined locations using lithography and crystallographic etching techniques. In various embodiments, cavities 112 are made using chemicals such as tetramethylammonium hydroxide (TMAH), potassium hydroxide (KOH), or EDP. This process allows the formation of accurate and precise crystallographic (111) planes or facets with about a 54.7-degree angle from a horizontal plane, thereby forming a pyramidal pit. At 702, the silicon substrate of the PIC die may additionally be thinned or built up (e.g., referencing views 200 and 250).

At 704, a feature is created on the glass waveguide substrate using available 3D structuring techniques, such as multi-photon absorption and selective etching. Laser assisted selective wet etching may be employed. Surface roughness in the feature after etching can be smoothed out using CO₂ (carbon dioxide) laser polishing. The features on the glass waveguide substrate are to mechanically connect with submicron precision to the sidewalls of the cavities in the top surface of the silicon of the silicon PIC 102 die.

At 706, an adhesive layer 332 may be overlaid on the PIC 102 die. The adhesive layer may be index-matching epoxy. At 708, the glass waveguide substrate and PIC die are attached to each other (i.e., mechanically placed/connected and kinematically coupled to each other). Accordingly, at 708, a feature is received by a respective cavity and has at least two regions that contact with sidewalls of the cavity, as described herein. In the first non-limiting example, there are three cavities and three matching features. In another non-limiting example, there are a plurality of cavities and a respective plurality of features. In still other embodiments, more than one feature can mate (attach or mechanically connect) within a single cavity, as described in connection with FIG. 5.

At 710, responsive to the kinematic coupling at 708, optical coupling of the main waveguides to respective waveguides in the glass waveguide substrate is achieved. Summarizing the method 700, it includes creating one or more cavities at predetermined locations in the PIC die using a crystallographic etching technique. As described herein, the one or more cavities are defined by respective sidewalls. Additionally, creating, for an individual cavity of the one or more cavities, a respective feature on the glass waveguide substrate that fits therein and contact respective sidewalls at two or more points. As used herein, “fit therein” refers to the dimensional/spatial relationship described and illustrated in connection to FIGS. 1B, 2A, and 3B; wherein the feature is shown fit within the cavity and contacting the sidewalls in at least 2 points.

The glass waveguide substrate may have optical fibers pre-assembled therein or have a connector interface that can readily attach to a ferrule with optical fibers that align with waveguides in the glass waveguide substrate. The kinematically aligned optical connector can be created to implement a variety of additional intricate alignment features on the kinematic connector interface, using the same 3D structuring techniques mentioned above.

Accordingly, various non-limiting embodiments of a system including a photonic integrated circuit (PIC) die with a kinematically aligned optical connector have been provided. In the following description and figures, additional context and applications for the embodiments described above are provided.

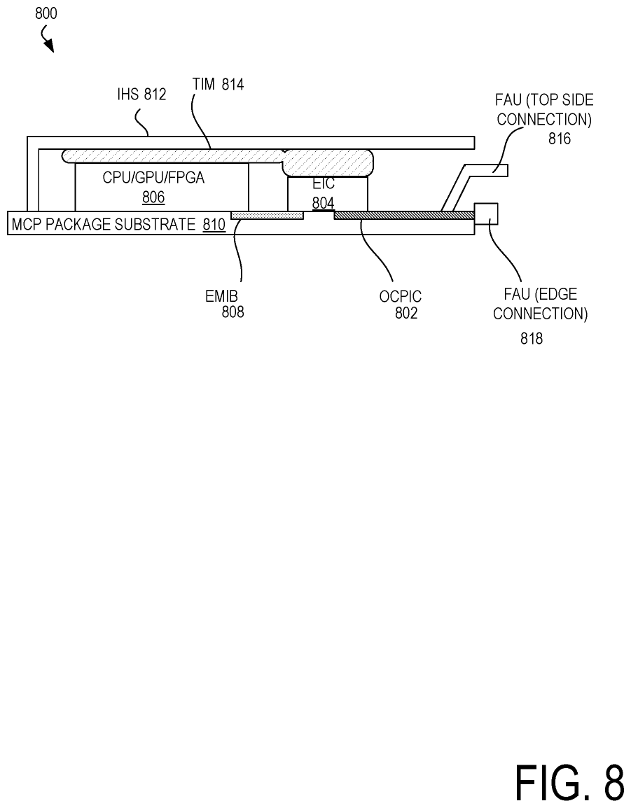

Turning now to FIG. 8, a PIC having the provided structure is implemented as an open cavity PIC (OCPIC) in a semiconductor assembly application, as may be assembled by a system integrator. A multi-die semiconductor assembly can be referred to as a multi-chip package (MCP) or, alternatively, a multi-chip module (MCM). FIG. 8 is a simplified cross-sectional side view of an exemplary multi-chip package (MCP) 800 that includes an OCPIC 802, in accordance with various embodiments. The MCP 800 may comprise one or more processor units, CPUs, graphics processors, or FPGAs, as represented by electronic integrated circuit (EIC) 804, and integrated circuit 806. In addition, the MCP 800 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets.”

In some embodiments, the OCPIC 802 chiplet is embedded in a MCP package substrate 810 (and the substrate of the OCPIC substrate is distinguished therefrom as PIC substrate, which may or may not be the same as the MCP package substate). In other embodiments, the OCPIC 802 chiplet is attached to a MCP package substrate 810. The OCPIC 802 is adjacent to the EIC 804 that is configured specifically to receive and process data from the OCPIC 802. In practice, interconnections between the dies and/or chiplets of MCP 800 can be provided by the MCP package substrate 810, one or more silicon interposers, one or more silicon bridges 708 embedded in the package substrate 810 (such as Intel® embedded multi-die interconnect bridges (EMIBs)), or combinations thereof. Silicon bridge 808 is shown to operationally couple the integrated circuit 806 with the electronic integrated circuit 804.

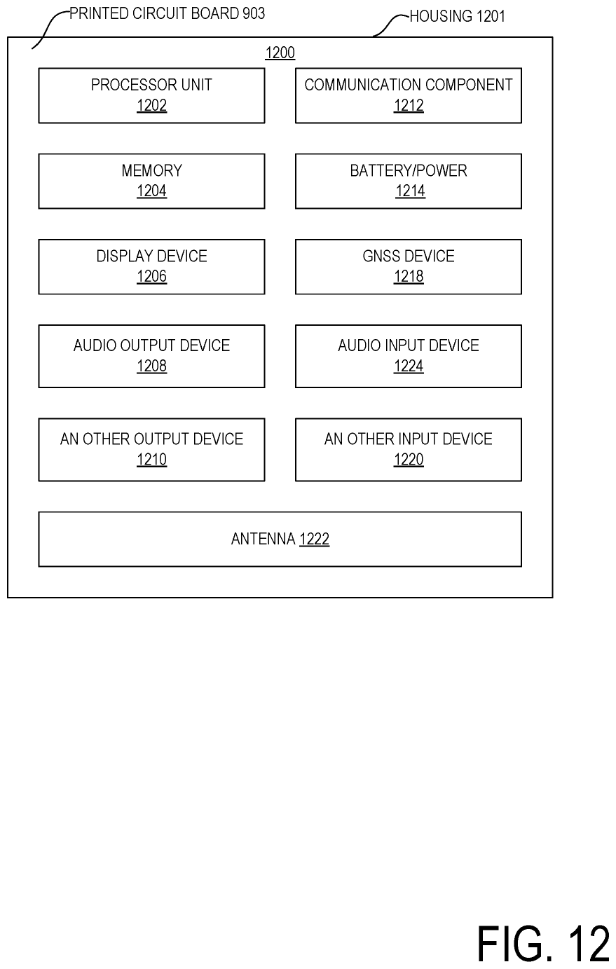

A thermal conduction layer interface material (TIM) 814 may be located over the integrated circuit 806 and the electronic integrated circuit 804. The TIM 814 can be any suitable material, such as a silver-particle filled thermal compound, thermal grease, phase change materials, indium foils or graphite sheets. An integrated heat spreader (IHS) 812, located on the TIM 814, covers the components of the MCP 800. In practice, the MCP 800, and the OCPIC 802 specifically, may communicate with other components in a device (e.g., device 1200, FIG. 12) via a fiber array unit (FAU) connector. In various embodiments, the FAU connector may be a top side connector 816, such as a grating coupler, or an edge connector 818, such as a micro-lens or V-groove.

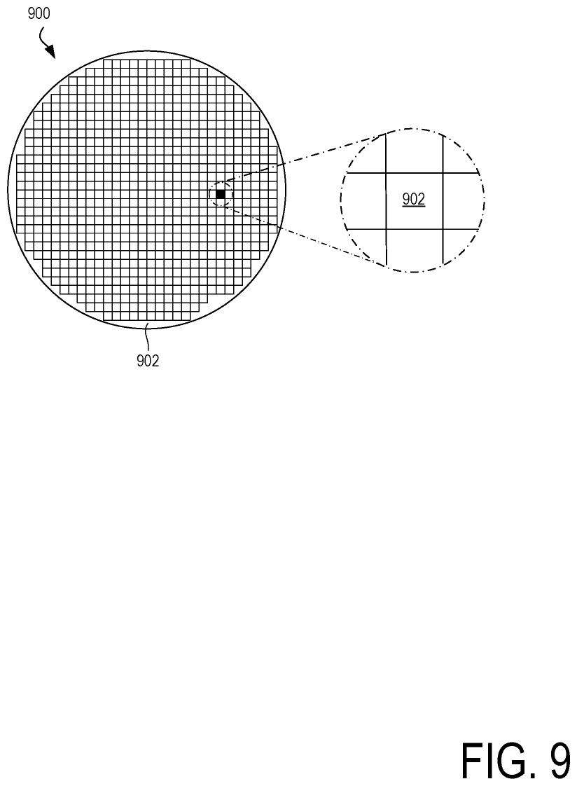

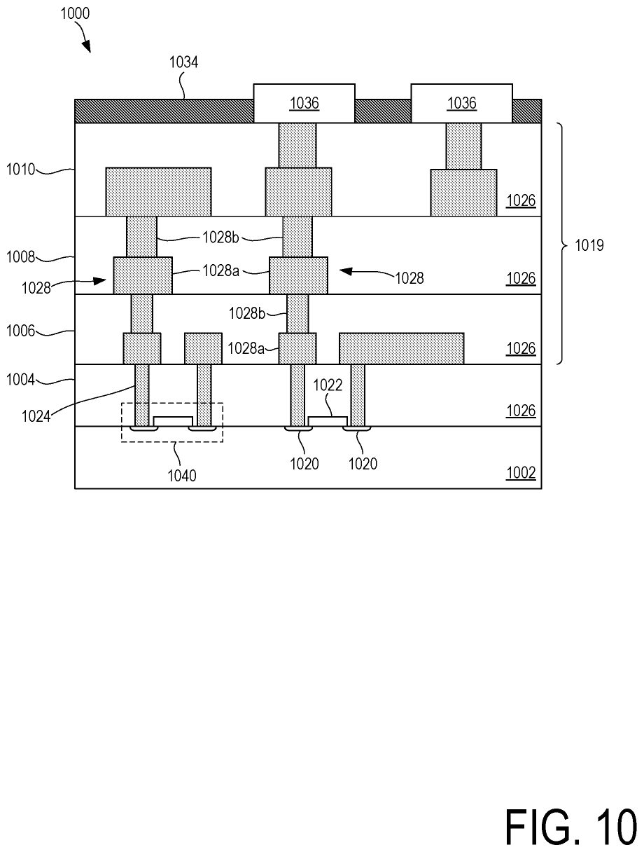

FIG. 9 is a top view of a wafer 900 and dies 902 that may be included in any of the embodiments disclosed herein. The wafer 900 may be composed of semiconductor material and may include one or more dies 902 formed on a surface of the wafer 900. After the fabrication of the integrated circuit components on the wafer 900 is complete, the wafer 900 may undergo a singulation process in which the dies 902 are separated from one another to provide discrete “chips” or destined for a packaged integrated circuit component. The individual dies 902, comprising an integrated circuit component, may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 902. For example, a memory array formed by multiple memory devices may be formed on a same die 902 as a processor unit (e.g., the processor unit 1202 of FIG. 12) or other logic that is configured to store information in the memory devices or execute instructions stored in the memory array. In some embodiments, a die 902 may be attached to a wafer 900 that includes other die, and the wafer 900 is subsequently singulated, this manufacturing procedure is referred to as a die-to-wafer assembly technique.

FIG. 10 is a cross-sectional side view of an integrated circuit 1000 that may be included in any of the embodiments disclosed herein. One or more of the integrated circuits 1000 may be included in one or more dies 902 (FIG. 9). The integrated circuit 1000 may be formed on a die substrate 1002 (e.g., the wafer 900 of FIG. 9) and may be included in a die (e.g., the die 902 of FIG. 9).

The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit 1000 may be used. The die substrate 1002 may be part of a singulated die (e.g., the dies 902 of FIG. 9) or a wafer (e.g., the wafer 900 of FIG. 9).

The integrated circuit 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020.

The gate 1022 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may comprise a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be conducted to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuits having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the interconnect structures 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit 1000 with another component (e.g., a printed circuit board). The integrated circuit 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit 1000 is a double-sided die, the integrated circuit 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit 1000 from the conductive contacts 1036.

In other embodiments in which the integrated circuit 1000 is a double-sided die, the integrated circuit 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit 1000 from the conductive contacts 1036. In some embodiments, TSVs extending through the substrate can be used for routing power and ground signals from conductive contacts on the opposite side of the integrated circuit 1000 from the conductive contacts 1036 to the transistors 1040 and any other components integrated into the die having the integrated circuit 1000, and the metallization stack 1019 can be used to route I/O signals from the conductive contacts 1036 to transistors 1040 and any other components integrated into the die having the integrated circuit 1000.

Multiple integrated circuits 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

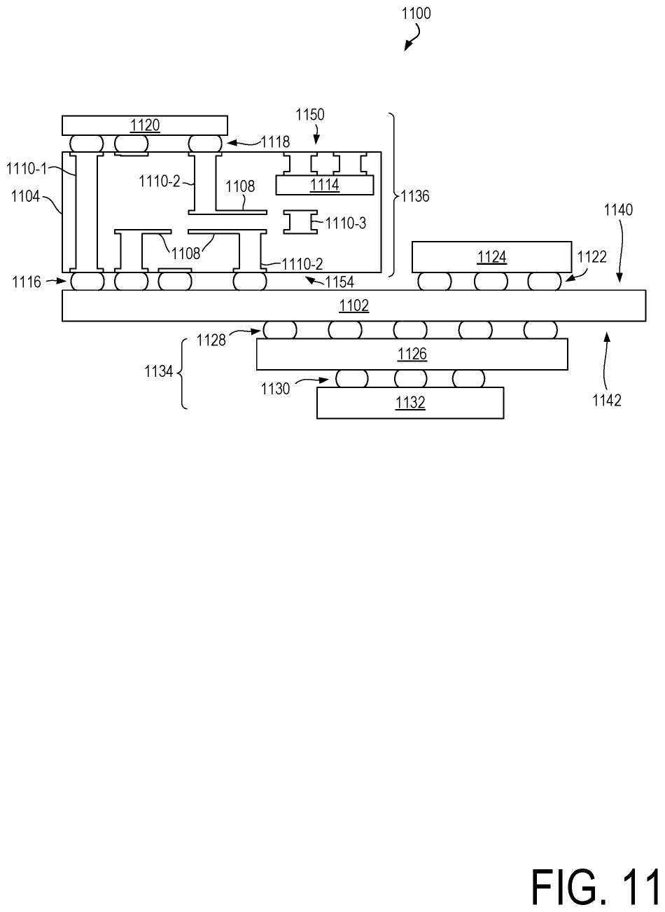

FIG. 11 is a cross-sectional side view of a microelectronic assembly 1100 that may include any of the embodiments disclosed herein. The microelectronic assembly 1100 includes multiple integrated circuit components disposed on a circuit board 1102 (which may be a motherboard, system board, mainboard, etc.). The microelectronic assembly 1100 may include components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The microelectronic assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit component that includes one or more integrated circuit dies (e.g., the die 902 of FIG. 9, the integrated circuit 1000 of FIG. 10) and/or one or more other suitable components.

The unpackaged integrated circuit component 1120 comprises solder bumps attached to contacts on the die. The solder bumps allow the die to be directly attached to the interposer 1104. In embodiments where the integrated circuit component 1120 comprises multiple integrated circuit dies; the dies can be of the same type (a homogeneous multi-die integrated circuit component) or of two or more different types (a heterogeneous multi-die integrated circuit component). In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets.” In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof. A packaged multi-die integrated circuit component can be referred to as a multi-chip package (MCP) or multi-chip module (MCM).

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on the first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The integrated circuit assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the microelectronic assemblies 1100, integrated circuit components 1120, integrated circuits 1000, integrated circuit dies 902, or structures disclosed herein. A number of components are illustrated in FIG. 12 as included in the electrical device 1200, but any one or more of these components may be omitted or duplicated, as suitable for the application. In some embodiments, some or all the components included in the electrical device 1200 may be attached to one or more motherboards, mainboards, printed circuit boards 903, or system boards. In some embodiments, one or more of these components are fabricated onto a single system-on-a-chip (SoC) die. In various embodiments, the electrical device 900 is enclosed by, or integrated with, a housing 901.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

Thus, embodiments of a structure for an open-cavity photonic integrated circuit (OCPIC) having a micro-ring resonator (MRR) have been provided. The provided embodiments advantageously enhance power efficiency of the MRR and the OCPIC. Embodiments enable the use of finer pitch architectures and high-density input/output (I/O) designs without impacting thermal efficiency.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc., means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

### Examples

Example 1 is an apparatus, comprising: a semiconductor substrate including a photonic integrated circuit (PIC), the PIC including waveguides, and the semiconductor substrate defining a cavity having sidewalls; a connector; and a glass waveguide substrate optically coupled to the waveguides of the PIC via the connector; wherein the connector is characterized by a feature including glass and extending from the glass waveguide substrate into the cavity, the feature having at least two regions that contact the sidewalls.

Example 2 includes the subject matter of Example 1, further comprising an adhesive layer located between the semiconductor substrate and the glass waveguide substrate.

Example 3 includes the subject matter of Example 1 wherein the feature is substantially hemispherical.

Example 4 includes the subject matter of Example 1, wherein the feature has a diameter in a range of about 40 microns to about 100 microns.

Example 5 includes the subject matter of Example 1, wherein the sidewalls include at least one portion defined by a slope of substantially 54.7 degrees.

Example 6 includes the subject matter of Example 1, wherein a portion of the glass waveguide substrate overlaps on the semiconductor substrate, and a corresponding region of the semiconductor substrate is thinned with respect to another region of the semiconductor substrate to receive the portion of the glass waveguide substrate.

Example 7 includes the subject matter of Example 1, wherein the cavity has an inverted pyramidal shape.

Example 8 includes the subject matter of Example 1, wherein the cavity corresponds to a v-groove.

Example 9 includes the subject matter of Example 1, wherein the waveguides in the PIC comprise silicon nitride.

Example 10 includes the subject matter of Example 1, wherein individual ones of the waveguides in the PIC are vertically optically coupled to the glass waveguide substrate.

Example 11 includes the subject matter of Example 1, wherein the semiconductor substrate further includes an edge cavity located alongside the waveguides in the PIC.

Example 12 includes the subject matter of Example 1, wherein the waveguides in the PIC are horizontally optically coupled to the glass waveguide substrate along a facet.

Example 13 includes the subject matter of Example 1, wherein the connector is a first connector, the cavity is a first cavity with first cavity sidewalls, and further comprising: the semiconductor substrate defining a second cavity having second sidewalls; a second feature that extends from the glass waveguide substrate into the second cavity at a first location, the second feature having at least two regions that contact the second sidewalls; and a third feature that extends from the glass waveguide substrate into the second cavity at a second location, away from the first location, the third feature having at least two regions that contact the second sidewalls; and wherein the glass waveguide substrate is optically coupled to the waveguides in the PIC further via second feature and the third feature.

Example 14 is a semiconductor assembly, comprising: a package substrate; an electronic integrated circuit (EIC) die attached on the package substrate; a photonic integrated circuit (PIC) die comprising silicon waveguides in a silicon substrate, the silicon substrate defining two or more cavities having respective sidewalls, the PIC die attached on the package substrate and in communication with the EIC die; a glass waveguide substrate optically coupled at a first surface to the silicon waveguides via at least three features, wherein individual ones of the features extend from the first surface into a cavity of the two or more cavities and contact therein to respective sidewalls in at least two regions.

Example 15 includes the subject matter of Example 14, wherein a cavity of the two or more cavities has an inverted pyramid shape.

Example 16 includes the subject matter of Example 14, wherein a cavity of the two or more cavities is a v-groove.

Example 17 includes the subject matter of Example 14, further a processing unit attached on the package substrate and electrically coupled to the EIC die and PIC die.

Example 18 includes the subject matter of Example 17, further comprising a heat spreader component located over the processing unit and the EIC die.

Example 19 is a method, comprising: providing a crystalline substrate having a photonic integrated circuit (PIC) with silicon waveguides therein; using an etching technique to create one or more cavities at predetermined locations in the crystalline substrate, wherein the cavities have sidewalls, and angles of individual ones of the sidewalls correspond to 111 facets of the crystalline substrate; providing a glass waveguide substrate; creating on the glass waveguide substrate, for individual ones of the cavities, a respective feature that extends from the glass waveguide substrate into the cavity and has at least two regions thereon that contacts respective sidewalls; and attaching the glass waveguide substrate to the crystalline substrate such that individual ones of the cavities have therein a respective feature and the silicon waveguides are optically aligned with the glass waveguide substrate.

Example 20 includes the subject matter of Example 19, wherein individual ones of the sidewalls are at an angle of about 54.7 degrees with respect to a horizontal plane, and further comprising providing an adhesive layer between the PIC die and the glass waveguide substrate.

Example 21 is an apparatus, comprising: a crystalline substrate having a photonic integrated circuit (PIC) with silicon waveguides therein, and the crystalline substrate defining a cavity having sidewalls; wherein angles of individual ones of the sidewalls correspond to 111 facets of the crystalline substrate.

Example 22 is an apparatus, comprising a glass waveguide substrate including glass waveguides and a feature extending from a surface of the glass waveguide substrate and configured to kinematically connect within a cavity of a silicon substrate comprising a photonic integrated circuit with silicon waveguides; wherein the kinematic connection corresponds to an optical coupling of the silicon waveguides with glass waveguides in the glass waveguide substrate.

What is claimed is:

1. An apparatus, comprising:
a semiconductor substrate including a photonic integrated circuit (PIC), the PIC including waveguides, and the semiconductor substrate defining a cavity having sidewalls;
a connector;
a glass waveguide substrate optically coupled to the waveguides of the PIC via the connector; and
wherein the connector is characterized by a feature including glass and extending from the glass waveguide substrate into the cavity, the feature having at least two regions that contact the sidewalls.

2. The apparatus of claim 1, further comprising an adhesive layer located between the semiconductor substrate and the glass waveguide substrate.

3. The apparatus of claim 1, wherein the feature is substantially hemispherical.

4. The apparatus of claim 1, wherein the feature has a diameter in a range of about 40 microns to about 100 microns.

5. The apparatus of claim 1, wherein the sidewalls include at least one portion defined by a slope of substantially 54.7 degrees.

6. The apparatus of claim 1, wherein a portion of the glass waveguide substrate overlaps on the semiconductor substrate, and a corresponding region of the semiconductor substrate is thinned with respect to another region of the semiconductor substrate to receive the portion of the glass waveguide substrate.

7. The apparatus of claim 1, wherein the cavity has an inverted pyramidal shape.

8. The apparatus of claim 1, wherein the cavity corresponds to a v-groove.

9. The apparatus of claim 1, wherein the waveguides in the PIC comprise silicon nitride.

10. The apparatus of claim 1, wherein individual ones of the waveguides in the PIC are vertically optically coupled to the glass waveguide substrate.

11. The apparatus of claim 1, wherein the semiconductor substrate further includes an edge cavity located alongside the waveguides in the PIC.

12. The apparatus of claim 1, wherein the waveguides in the PIC are horizontally optically coupled to the glass waveguide substrate along a facet.

13. The apparatus of claim 1, wherein the connector is a first connector, the cavity is a first cavity with first cavity sidewalls, and further comprising:
the semiconductor substrate defining a second cavity having second sidewalls;
a second feature that extends from the glass waveguide substrate into the second cavity at a first location, the second feature having at least two regions that contact the second sidewalls; and
a third feature that extends from the glass waveguide substrate into the second cavity at a second location, away from the first location, the third feature having at least two regions that contact the second sidewalls; and
wherein the glass waveguide substrate is optically coupled to the waveguides in the PIC further via second feature and the third feature.

14. A semiconductor assembly, comprising:
a package substrate;
an electronic integrated circuit (EIC) die attached on the package substrate;
a photonic integrated circuit (PIC) die comprising silicon waveguides in a silicon substrate, the PIC die defining two or more cavities having respective sidewalls, the PIC die attached on the package substrate and in communication with the EIC die; and
a glass waveguide substrate optically coupled at a first surface to the silicon waveguides via at least three features, wherein individual ones of the features extend from the first surface into a cavity and contact therein to respective sidewalls in at least two regions.

15. The semiconductor assembly of claim 14, wherein a cavity has an inverted pyramid shape.

16. The semiconductor assembly of claim 14, wherein a cavity is a v-groove.

17. The semiconductor assembly of claim 14, further a processing unit attached on the package substrate and electrically coupled to the EIC die and PIC die.

18. The semiconductor assembly of claim 17, further comprising a heat spreader component located over the processing unit and the EIC die.

19. A method, comprising:
providing a crystalline substrate having a photonic integrated circuit (PIC) with silicon waveguides therein;
using an etching technique to create one or more cavities at predetermined locations in the crystalline substrate, wherein the cavities have sidewalls, and angles of individual ones of the sidewalls correspond to 111 facets of the crystalline substrate;
providing a glass waveguide substrate;
creating on the glass waveguide substrate, for individual ones of the cavities, a respective feature that extends from the glass waveguide substrate into the cavity and has at least two regions thereon that contacts respective sidewalls; and
attaching the glass waveguide substrate to the crystalline substrate such that individual ones of the cavities have therein a respective feature and the silicon waveguides are optically aligned with the glass waveguide substrate.

20. The method of claim 19, wherein individual ones of the sidewalls are at an angle of about 54.7 degrees with respect to a horizontal plane, and further comprising providing an adhesive layer between the PIC die and the glass waveguide substrate.
